(19) United States
(12) Patent Application Publication
(10) Pub. No.: US 2023/0262897 A1
(43) Pub. Date: Aug. 17, 2023

(54) BATTERY PACK

(71) Applicant: BLACK & DECKER INC., New Britian, CT (US)

(72) Inventors: Michael SIKORA, Baltimore, MD (US); Abraham LOZIER, Kingsville, MD (US); Craig ARMACOST, Parkton, MD (US)

(21) Appl. No.: 18/109,750

(22) Filed: Feb. 14, 2023

Related U.S. Application Data
(60) Provisional application No. 63/267,962, filed on Feb. 14, 2022.

(51) Int. Cl. H05K 1/14; H01M 50/204; H01M 10/42; H01M 50/284

(52) U.S. Cl. CPC H05K 1/144; H01M 50/204; H01M 10/425; H01M 50/284; H05K 2201/042; H05K 2201/10037; H01M 2010/4271

(57) ABSTRACT

A battery pack including a first printed circuit board, a second printed circuit board, and a PCB spacer, the PCB spacer including a housing and at least two board-to-board terminals, the PCB spacer housing injection molded around the board-to-board terminals, wherein the first printed circuit board coupled to a first side of the PCB spacer and the second printed circuit board coupled to a second side of the PCB spacer, the first side of the PCB spacer being opposed to the second side of the PCB spacer.

### RELATED APPLICATIONS

This application claims priority under 35 U.S.C. § 119(e) to U.S. Provisional Patent Application No. 63/267,962, filed Feb. 14, 2022, titled “Battery Pack.”

### TECHNICAL FIELD

This application relates to a battery pack and a method for manufacturing and operating a battery pack.

### BACKGROUND

Controlling power paths in lithium ion battery packs typically requires large amounts of printed circuit board (PCB) surface area to accommodate the proper copper tracing and heatsinking. Historically, battery pack power management is handled on a single PCB. Increasing or additional management solutions tend to result in large battery pack enclosures to accommodate a large PCB. However, in order to reduce the form factor of a battery pack, one must either eliminate features or produce unique battery management solutions.

The instant application describes an example battery pack for providing electric power to a cordless power tool or other electrical or electronic device.

### SUMMARY

An aspect of the present invention includes a battery pack including a housing and a core pack. The housing may include an upper portion and a lower portion. The upper portion and the lower portion form an internal space or cavity when coupled together. The core pack is positioned within the internal space. The core pack includes a battery pack terminal block. The terminal block includes a plastic housing. The core pack also includes a battery cell holder containing a plurality of battery cells. The battery cells are connected together forming a string of battery cells.

Another aspect of the present invention includes an example battery pack including a first printed circuit board, a second printed circuit board, and a PCB spacer, the PCB spacer including a housing and at least two board-to-board terminals, the PCB spacer housing injection molded around the board-to-board terminals, wherein the first printed circuit board coupled to a first side of the PCB spacer and the second printed circuit board coupled to a second side of the PCB spacer, the first side of the PCB spacer being opposed to the second side of the PCB spacer.

In the foregoing embodiment of the example battery pack the board-to-board terminals electrically may connect the first printed circuit board to the second printed circuit board.

In the foregoing embodiment of the example battery pack the first printed circuit board may include terminal holes to receive the board-to-board terminals and the second PCB includes terminal holes to receive the board-to-board terminals.

In the foregoing embodiment of the example battery pack the first printed circuit board terminal holes may be electrically coupled to components mounted on the first printed circuit board and the second printed circuit board terminal holes may be electrically coupled to components mounted on the second printed circuit board.

In the foregoing embodiment of the example battery pack the board-to-board terminals may include a conductive metal material.

In the foregoing embodiment of the example battery pack the spacer housing may have a generally planar, rectangular shape.

In the foregoing embodiment of the example battery pack the PCB spacer may include a plastic material.

In the foregoing embodiment of the example battery pack the PCB spacer may be formed by an injection molding process.

In the foregoing embodiment of the example battery pack the spacer housing may include at least one clip extending from the first side of the spacer housing and the clip may clip onto the first printed circuit board to couple and hold the spacer housing on the first printed circuit board.

In the foregoing embodiment of the example battery pack, the battery pack may further include a first battery strap wherein the first battery strap may electrically and mechanically couple to the first PCB.

In the foregoing embodiment of the example battery pack the first battery strap may include an end that is received in a first battery strap hole in the first PCB.

In the foregoing embodiment of the example battery pack the first battery strap hole may be electrically coupled to components mounted on the first printed circuit board.

In the foregoing embodiment of the example battery pack, the battery pack may further include a battery pack housing, wherein the battery pack housing may form an interior cavity, a set of battery cells, a battery cell holder housing the set of battery cells, wherein the battery cell holder may be positioned within the interior cavity, and wherein the first printed circuit board may be coupled to the battery cell holder.

In the foregoing embodiment of the example battery pack the first battery strap may be electrically coupled to a contact pad that is electrically connected to a most negative terminal of the set of battery cells.

In the foregoing embodiment of the example battery pack the PCB spacer may include an interior opening defined by sides of the spacer housing, wherein the interior opening may receive one or more of a plurality of components mounted on a surface of the first printed circuit board facing the PCB spacer.

In the foregoing embodiment of the example battery pack the interior opening may be filled with a potting material to protect the mounted components from contaminants.

In the foregoing embodiment of the example battery pack, the battery pack may further include a hold-down screw mechanically coupling the second printed circuit board and the PCB spacer to the first printed circuit board.

In the foregoing embodiment of the example battery pack the first printed circuit board may include a threaded surface mounted nut and the hold-down screw may be received by and screwed into the nut.

Implementations of this aspect may include one or more of the following features.

Advantages may include one or more of the following.

These and other advantages and features will be apparent from the description and the drawings.

### BRIEF DESCRIPTION OF THE DRAWINGS

FIG. 1 illustrates an example battery pack.

FIG. 2 illustrates an exploded view of the battery pack of FIG. 1.

FIGS. 3A and 3B illustrate multiple views of an example corepack of the battery pack of FIG. 1.

FIGS. 4A and 4B illustrate additional view of the core pack of FIGS. 3A and 3B.

FIGS. 5A and 5B illustrate partial exploded views of the core pack of FIGS. 3A and 3B.

FIGS. 6A, 6B, and 6C illustrate additional exploded views of the core pack of FIGS. 3A and 3B.

FIG. 7 illustrates a section view of FIG. 6C along line A-A.

FIGS. 8A and 8B illustrate multiple views of printed circuit board subassembly of the battery pack of FIG. 1.

FIGS. 9A and 9B illustrate additional views of the printed circuit board subassembly of FIGS. 8A and 8B.

FIGS. 10A, 10B and 10C illustrate exploded views of the printed circuit board subassembly of FIGS. 8A and 8B.

FIG. 11 illustrates multiple views of an example printed circuit board spacer.

### DETAILED DESCRIPTION

In a preferred embodiment, a lithium ion battery pack should control discharge of the battery cells to avoid premature failure. This requires monitoring power current output, output time, pack temperature, and then controlling all those parameters. The example battery pack may use high power MOSFETs to break the power current path to stop excessive discharge currents. This MOSFET control scheme is accomplished with an auxiliary PCB coupled to a battery pack main (primary) control PCB. The auxiliary PCB is stacked on top of the main control PCB for the smallest form factor solution. This can essentially double the PCB surface area while maintaining a compact footprint inside the battery pack housing.

The main control PCB and auxiliary PCB are connected via soldered board-to-board terminals and signal level connectors. A high temperature plastic spacer is placed between the main PCB and the auxiliary PCB to provide alignment and mechanical support. A fastener is used to mechanically couple the two PCBs together. The soldered terminals are used for a high current (power) path while a conductive pin connector is used for the low current (signal level) connections. The signal connector communicates to the main control PCB to turn the MOSFETs on or off to open or close the battery power current path. When the MOSFETs are on, they must handle the full current draw experienced by the battery pack during tool use. The potential for prolonged high current draw requires additional surface mounted heatsinks on the auxiliary PCB to lower the temperature of the MOSFETs.

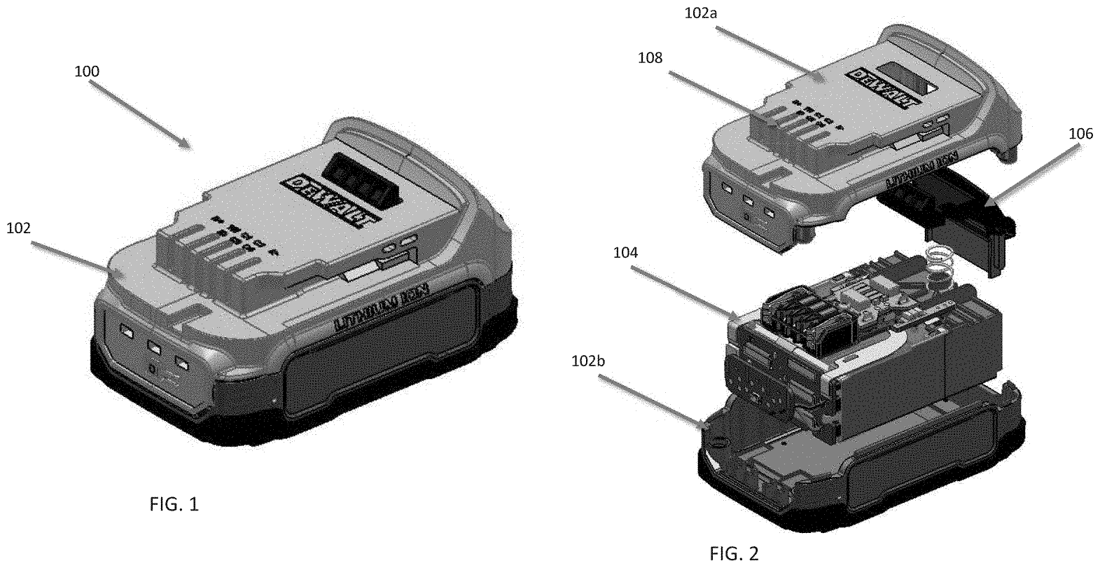

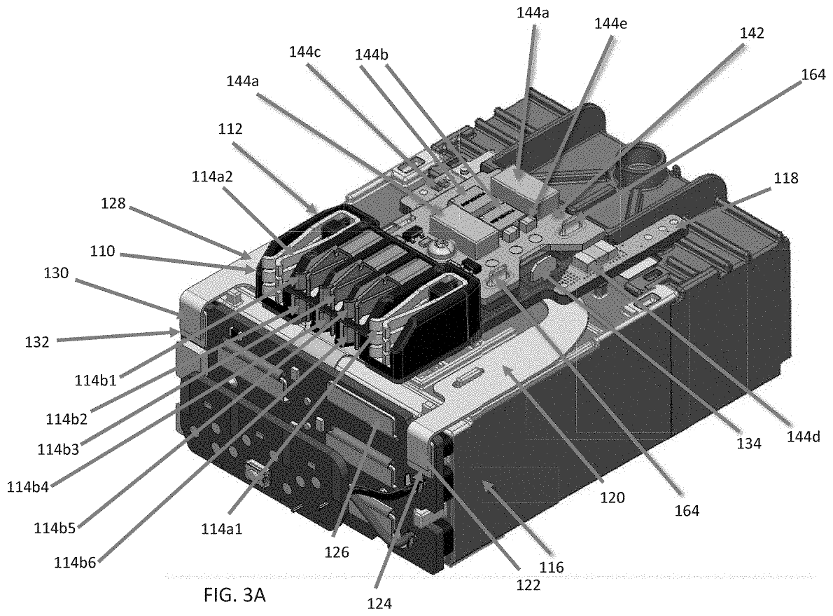

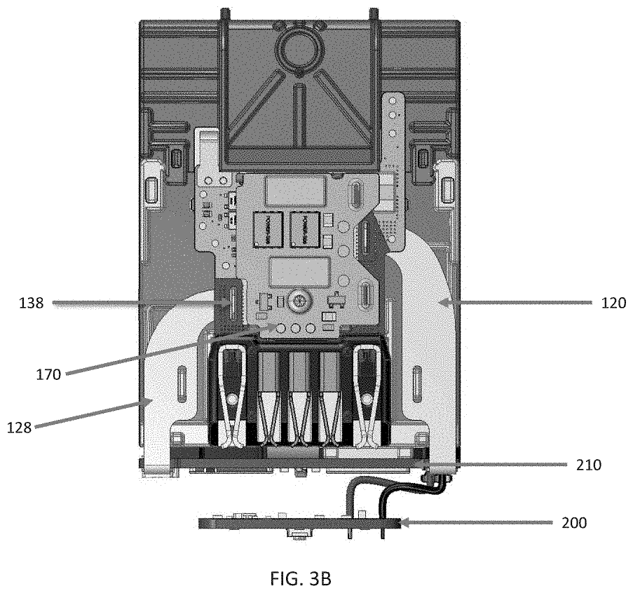

As illustrated in FIGS. 1 and 2, there is disclosed a battery pack 100. The battery pack 100 may include a housing 102 and a core pack 104. The housing 102 may include an upper housing portion 102a, a lower housing portion 102b, and a latch 106. The upper housing portion 102a may include a plurality of slots 108 or openings. The upper portion and the lower portion may form an internal space or cavity when coupled together. The core pack 104 may be positioned within the internal space. The core pack 104 may include a battery pack terminal block 110. The terminal block 110 may include a housing 112 and a plurality of battery pack terminals 114 (also referred to as a set of battery pack terminals). The plurality of battery pack terminals 114 may include a subset of power terminals 114a including a negative terminal 114a1—alternatively referred to as a BATT—terminal—and a positive terminal 114a2—alternatively referred to as a BATT+ terminal. The BATT− terminal 114a1 and the BATT+ terminal 114a2 may couple to corresponding terminals of a power tool (TOOL− terminal and TOOL+ terminal) to which the battery pack 100 is configured and designed to provide power. The terminal block housing 112 may be made of a plastic. The terminal block housing 112 fixedly positions the battery pack terminals 114 relative to each other and the other components of the battery pack 100. The core pack 104 may include a plurality of battery cells (not shown). The battery cells may be electrically coupled together to form a string of battery cells. The string of battery cells may have a most negative terminal or node and a most positive terminal or node. The core pack 104 may include a battery cell holder 116. The battery cell holder 116 holds the battery cells and fixedly positions the battery cells relative to each other and the other components of the battery pack 100.

The core pack 104 may include a first printed circuit board (PCB) 118—sometimes alternatively referred to as a primary PCB or a main control PCB. The first PCB 118 may be coupled to the cell holder. The terminal block 110, including the battery pack terminals 114, may be electrically and mechanically coupled to the first PCB 118. The core pack 104 may include a first battery strap 120—alternatively referred to as a B− battery strap and a second battery strap 128—alternatively referred to as a B+ battery strap. The B− battery strap 120 may include a first end 122 that may be electrically coupled to a contact pad 124 that is electrically connected to the most negative terminal/tab 126 of the string of battery cells and the B+ battery strap 128 may include a first end 130 that may be electrically coupled to a contact pad 132 that is electrically connected to the most positive terminal/tab (not illustrated) of the string of battery cells. The B− battery strap 120 may include a second end 134 that is received in a first hole/via 136 in the first PCB 118 (the hole/via 136 having an electrical connection to other components on the first PCB 118) and the B+ battery strap 128 may include a second end 138 that is received in a second hole/via 140 in the first PCB 118 (the second hole/via 140 having an electrical connection to other components on the first PCB 118) and both the B− battery strap 120 and the B+ battery strap 128 may also be electrically and mechanically coupled to the first PCB 118 by, for example, soldering the second end 134 of the B− battery strap 120 and the second end 138 of the B+ battery strap 128 to the first hole 136 and the second hole 140 in the first PCB 118, respectively.

The battery pack 100 may include a second PCB 142—alternatively referred to as an auxiliary PCB. The second PCB 142 may include a plurality of components 144 mounted to the surface of the PCB. These components 144 may include, but are not limited to, one or more heat sinks 144a, one or more switches 144b, e.g., field effect transistors (FETs), resistors 144c, shunts 144d and capacitors 144e.

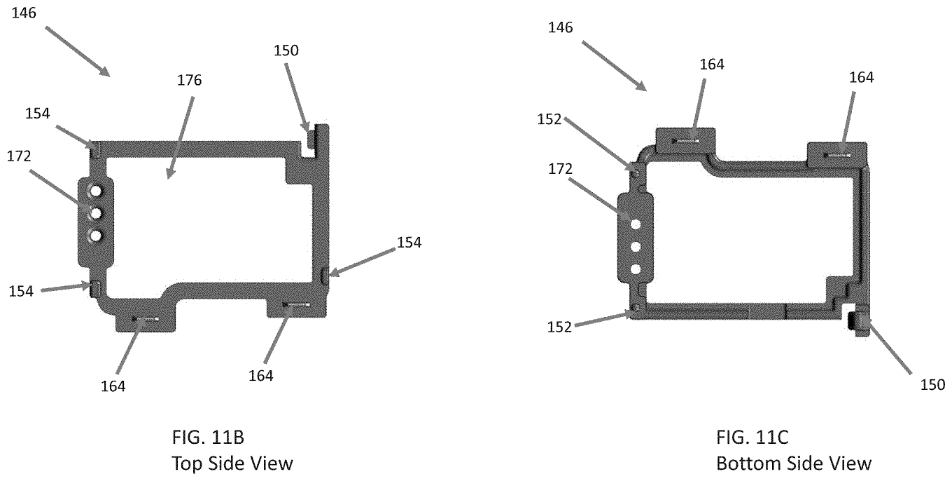

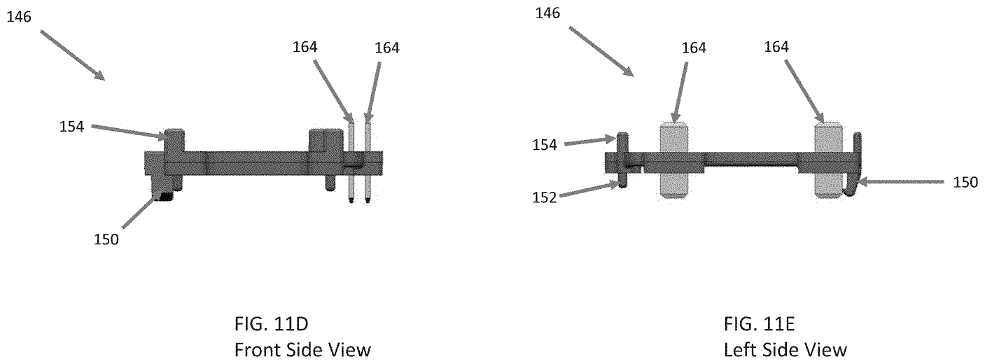

The battery pack 100 may include a PCB spacer 146. The PCB spacer 146 may be made of a plastic material. The PCB spacer 146 may be formed by an injection molding process. The PCB spacer 146 may be mechanically coupled to the first PCB 118 and the second PCB 142 may be mechanically coupled to the PCB spacer 146. As illustrated in FIG. 11, the PCB spacer 146 may include a housing 148. The spacer housing 148 may have a generally planar, rectangular shape. A first side of the plane of the spacer housing 148 (illustrated, for example, in FIG. 11C) may face the first PCB 118 when the spacer housing 148 is coupled to the first PCB 118. A second side of the plane of the spacer housing 148 (illustrated, for example, in FIG. 11B) may be opposed to the first side of the plane.

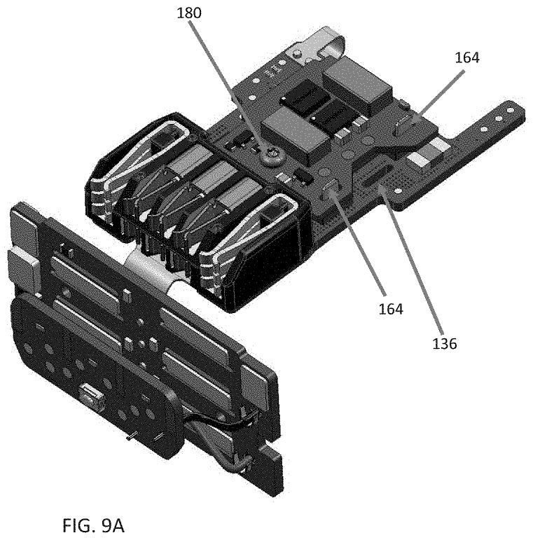

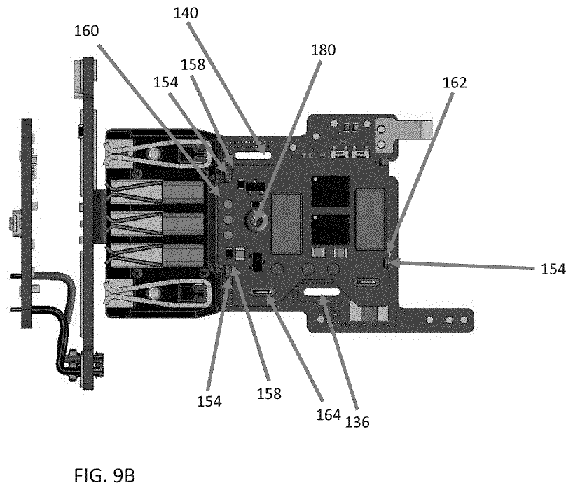

The spacer housing 148 may include at least one clip 150 extending from the first side of the spacer housing 148. The clip 150 may be configured to clip onto the first PCB 118 to couple and hold the spacer housing 148 on the first PCB 118. The PCB spacer housing 148 may be formed with and include at least one alignment pin 152 extending from the first side and at least one alignment post 154 extending from the second side of the spacer housing 148. The first PCB 118 may include alignment holes 156 configured to receive the alignment pins 152 to properly align the PCB spacer 146 when the PCB spacer 146 is placed on and coupled to the first PCB 118. The alignment post 154 may be configured to align the second PCB 142 when the second PCB 142 is placed on and coupled to the PCB spacer 146. As illustrated, for example, in FIG. 9B, the second PCB 142 may be formed with a pair of shoulders 158 at a forward end thereof, forming a neck 160. When the second PCB 142 is placed on the spacer 146, the alignment posts 154 at a forward end of the spacer 146 are positioned at the shoulders 158 and on either side of the neck 160 to assist in aligning the second PCB 142 on the spacer 146. Furthermore, the second PCB may be formed with a cutout 162 at a rearward end thereof. When the second PCB 142 is placed on the spacer 146, the alignment post 154 at a rearward end of the spacer 146 is positioned at the cutout 162 to assist in aligning the second PCB 142 on the spacer 146.

The PCB spacer 146 may include at least two board-to-board terminals 164. The board-to-board terminals 164 may be made of a conductive metal material, such as copper. The PCB spacer 146 may be injection molded around the board-to-board terminals 164. The first PCB 118 may include terminal holes 166 to receive the board-to-board terminals 164 when the PCB spacer 146 is placed on and coupled to the first PCB 118. The second PCB 142 may include terminal holes 168 to receive the board-to-board terminals 164 when the second PCB 142 is placed on and coupled to the spacer housing 148. When the second PCB 142 is mounted to the PCB spacer 146 and the board-to-board terminals 164 are received in the terminal holes 166 in the first PCB 118 and terminal holes 168 in the second PCB 142, and the board-to-board terminals 164 are fixed to the first PCB 118 and to the second PCB 142, for example by soldering, the second PCB 142 is electrically and mechanically couple to the first PCB 118 providing a current path for the discharge (power) current path.

The second PCB 142 may include a plurality of board-to-board connection pins 170—alternatively referred to as nail head pins, extending from the second PCB 142 towards the first PCB 118. These pins 170 are used to transmit/conduct relatively low current, data signals between the first PCB 118 and the second PCB 142 and from the first PCB 118 to a subset of sense/signal terminals 114b. The PCB spacer 146 may include a corresponding number of pin holes 172 to allow the pins 170 to pass through the PCB spacer 146. The first PCB 118 may also include a corresponding number of holes 174 to receive the board-to-board connection pins 170. When the second PCB 142 is mounted to the PCB spacer 146 and the board-to-board pins 170 are received in the holes 174 in the first PCB 118, and the board-to-board connection pins 170 are fixed to the first PCB 118, for example by soldering, the second PCB 142 is electrically and mechanically couple to the first PCB 118 providing a current path for the signal (data) current path.

The PCB spacer 146 may include an interior opening 176 defined by the rectangular sides of the spacer housing 148. The interior opening 176 may be configured to receive one or more of a plurality of components mounted on a surface of the first PCB 118 facing the PCB spacer 146. Upon placement of the PCB spacer 146 on the first PCB 118, the interior opening 176 may be filled with a potting material to protect the mounted components from contaminants.

When the PCB spacer 146 is mounted to the first PCB 118 and the second PCB 142 is mounted to the PCB spacer 146 a hold-down screw 180 may mechanically couple the second PCB 142 and the PCB spacer 146 to the first PCB 118. The first PCB 118 may include a threaded surface mounted nut 182 fixed to, for example soldered, the first PCB 118. The hold-down screw 180 is received by and screwed into the nut 182.

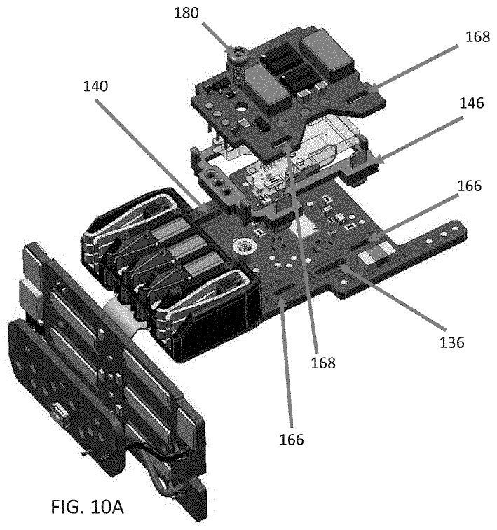

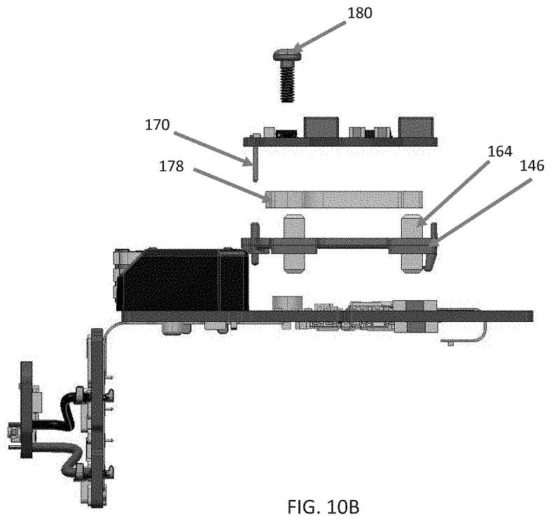

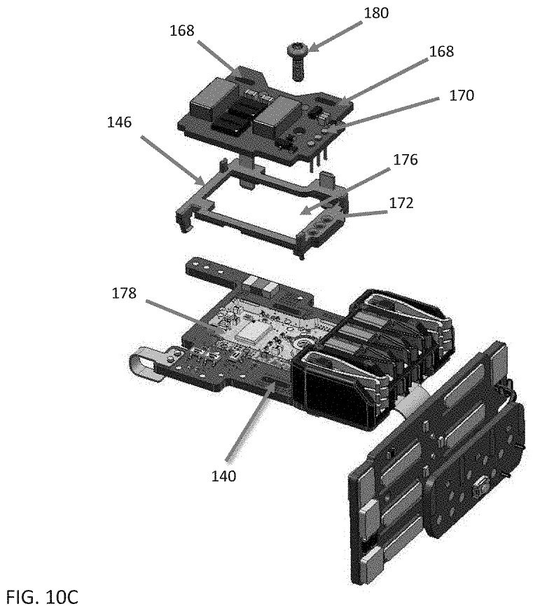

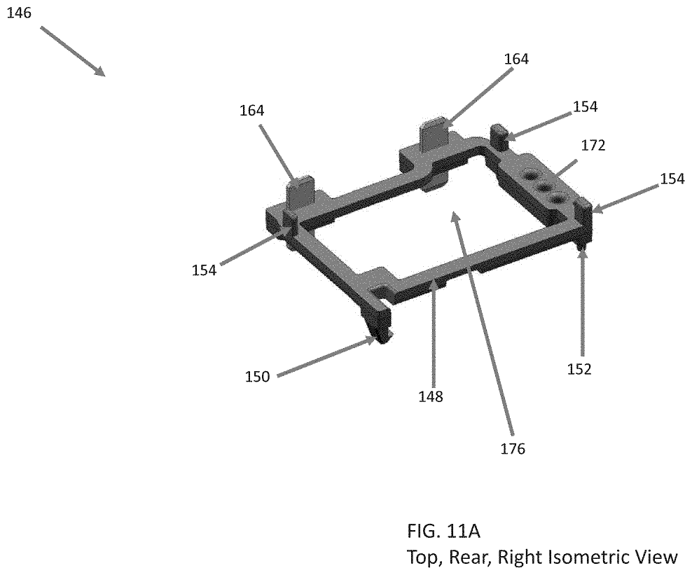

In a first example, the battery pack may be assembled in the following manner. As illustrated in FIGS. 10A-10C, a state of charge printed circuit board 200 may be electrically coupled to a battery cell lead collection board 210. The battery cell lead collection board 210 may be electrically coupled the first printed circuit board 118. The battery pack terminal block 110 including the battery pack terminal housing 112 and the battery pack terminals 114 may be mechanically and electrically coupled to the first printed circuit board 118.

The PCB spacer 146 may be coupled to the first printed circuit board 118. When this step occurs, the alignment pins 152 at a forward end of the PCB spacer are received in the alignment holes 156 of the first printed circuit board 118 and a first end of the board-to-board terminals 164 are received in the terminal holes 166 in the first printed circuit board 118 and the clip 150 engages and hooks onto a rearward end of the first printed circuit board 118.

At this point, for example, the first end of the board-to-board terminals 164 are electrically coupled to the first printed circuit board 118, for example, by soldering.

At this point, for example, a potting material is placed into the PCB spacer interior opening 176 to cover and protect any surface mounted components within the interior opening 176.

The second printed circuit board 142 may be placed onto the PCB spacer 146. When this occurs, a second end of the board-to-board terminals 164 are received in the terminal holes 168 in the second printed circuit board 142 and the board-to-board terminal pins 170 are received through the spacer pin holes 172 and into the pin holes 174 of the first printed circuit board 118.

At this point, for example, the second end of the board-to-board terminals 164 are electrically coupled to the second printed circuit board 142, for example, by soldering and ends of the board-to-board pins 170 are electrically coupled to the first printed circuit board 118, for example, by soldering.

The hold-down screw 180 is then passed though a hole in the second printed circuit board and receive and screwed into the threaded surface mounted nut 182.

At this point, a PCB subassembly has been formed, as illustrated in FIGS. 9A and 9B.

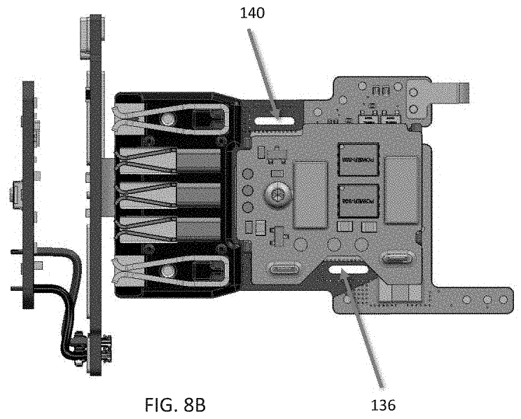

Thereafter, a surface coating may be applied to the second printed circuit board 142 and the exposed areas of the first printed circuit board 118, as illustrated in FIGS. 8A and 8B.

Thereafter, the PCB subassembly may be mounted to a forward portion of the cell holder 116.

Thereafter, a plurality of battery cells may be inserted into the forward portion of the cell holder 116 such that the tabs of the battery cells are received in slots in the battery cell lead collection board 210. A rearward portion of the cell holder is mechanically coupled to the forward portion of the cell holder to hold the battery cells in place. Thereafter, the tabs of the battery cells are electrically coupled to contact pads 220 in the lead collection board 210, for example, by laser welding, thereby forming a string of battery cells. Thereafter, the first battery strap 120 and the second battery strap 128 are placed on the battery cell holder 116. The first end 122 of the first battery strap 120 and the first end 130 of the second battery strap 128 are electrically coupled to the contact pad 124 and the contact pad 132, respectively, on the lead collection board 210.

Thereafter, the first printed circuit board 118 is placed on the cell holder 116 such that the second end 134 of the first battery strap 120 is received in the first hole 136 of the first printed circuit board 118 and the second end 138 of the second battery strap 128 is received in the second hole 140 of the first printed circuit board 118.

At this point, for example, the second end 134 of the first battery strap 120 and the second 138 of the second battery strap 128 are electrically coupled to the first printed circuit board 118, for example, by soldering.

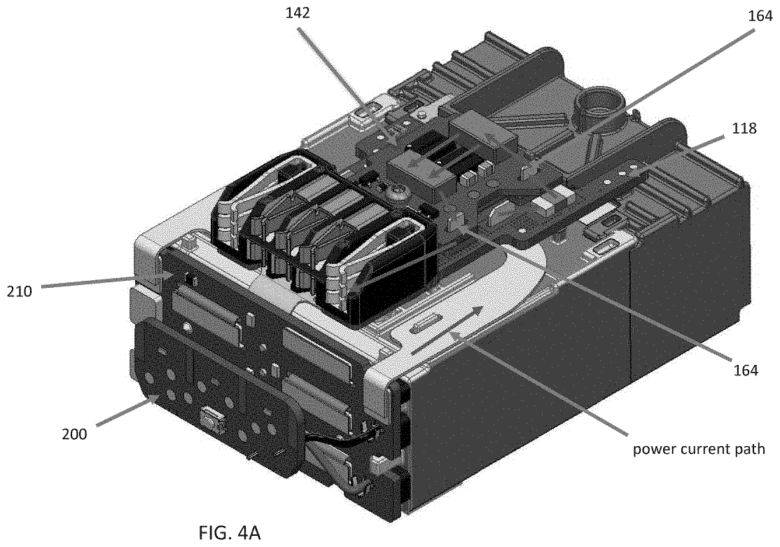

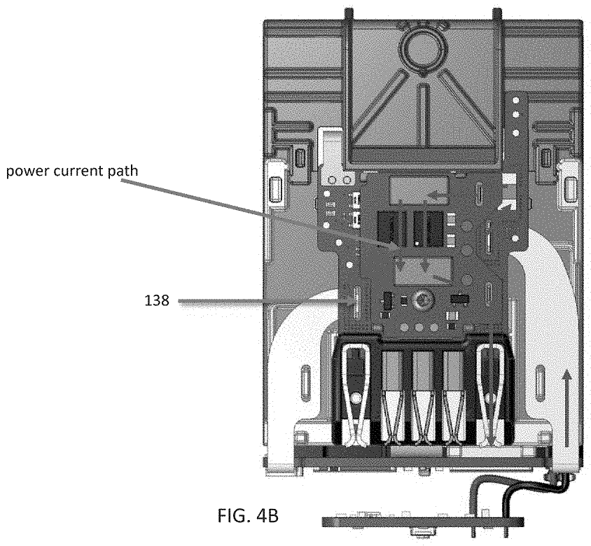

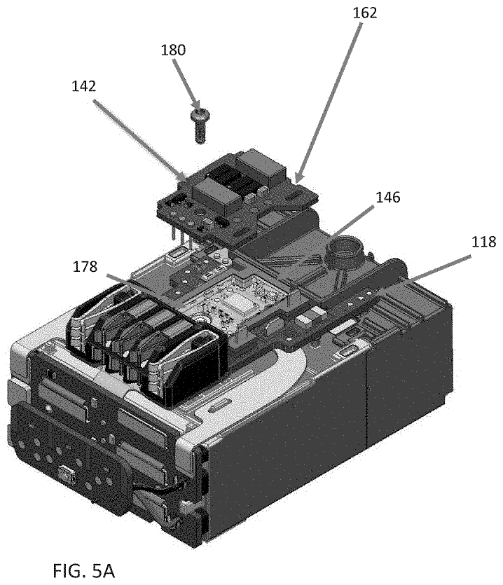

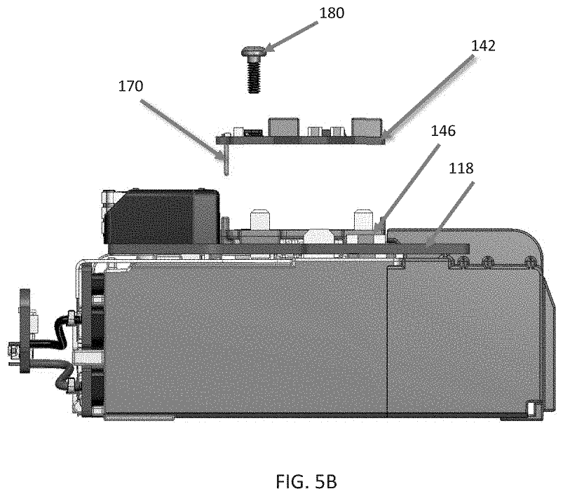

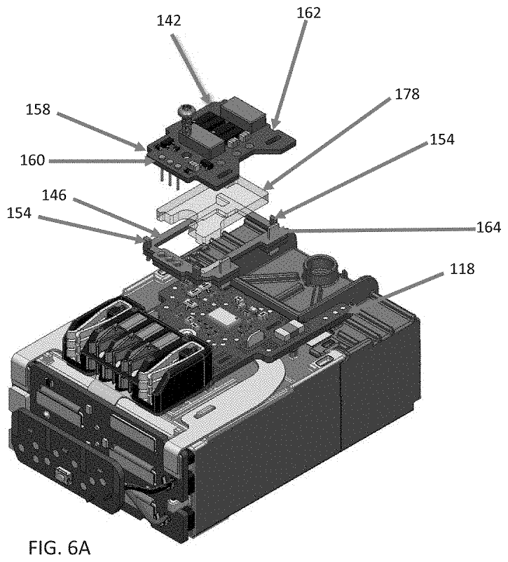

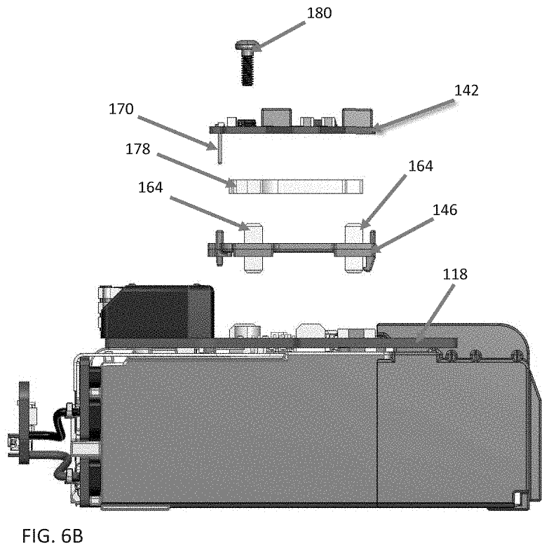

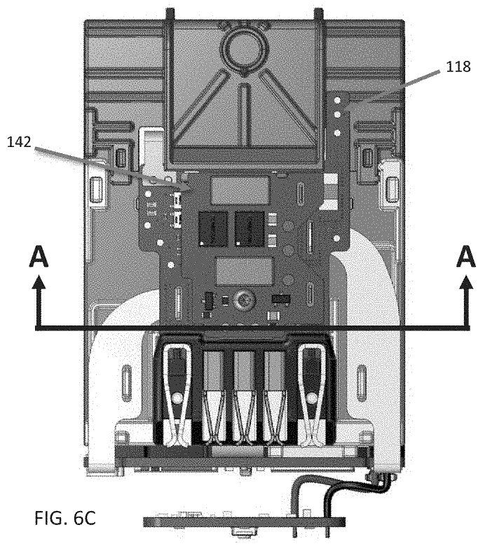

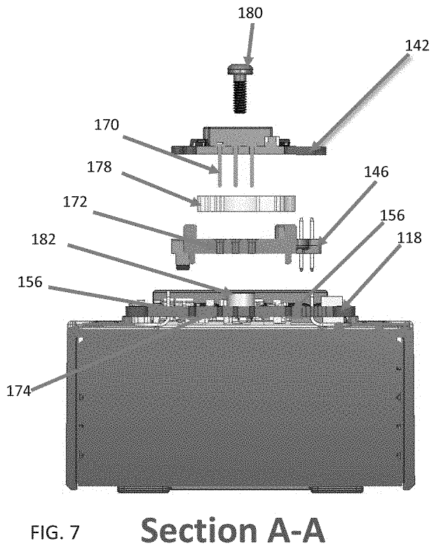

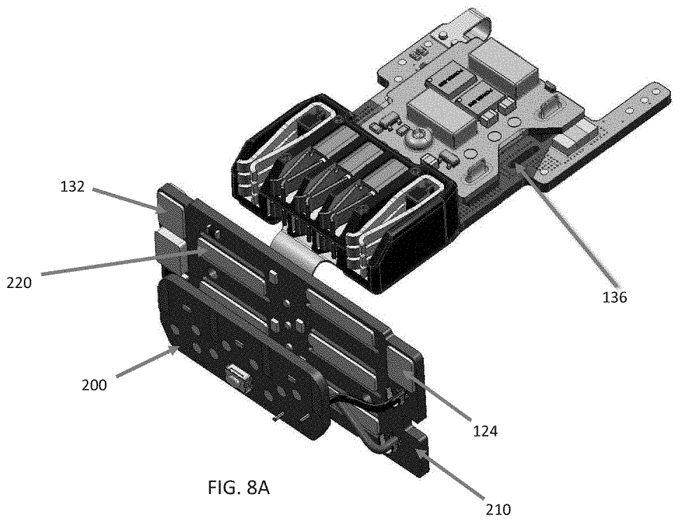

At this point, the battery pack core pack 104 has been formed, as illustrated in FIGS. 4A and 4B.

Thereafter, the core pack 104 may be assembled with the latch 106 and the upper housing portion 102a and the lower housing portion 102b to form the finished battery pack 100.

Once the core pack 104 is formed, as illustrated in FIGS. 4A and 4B, a power current path is formed between the negative most terminal/tab 126 of the string of battery cells and the negative power terminal 114a1. This power current path passes through the negative battery strap 128 to the first printed circuit board 118 then through components on the first printed circuit board 118 including but not limited to the shunt 144d, then through a first board-to-board terminal 164 to the second print circuit board 142 then through components on the second printed circuit board 142 including but not limited to a first heat sink 144a1, a set of switches 144b and then to a second board-t-board terminal 164 back to the first printed circuit board 118 then to the negative power terminal 114a1.

During operation, if a microprocessor in the battery pack 100, for example a microprocessor mounted on the first printed circuit board 118, determines that the battery pack is overheating or has exceeded a current threshold or has exceeded a voltage threshold, either during charging or discharging, the microprocessor can open the set of switches 144b. This will open the power current path and prevent damage to the battery pack.

The foregoing description illustrates the claimed invention by way of example and not by way of limitation. The description clearly enables one skilled in the art to make and use the disclosure, describes several example embodiments, adaptations, variations, alternatives, and uses of the disclosure, including what is presently believed to be the best mode of carrying out the claimed invention. Additionally, it is to be understood that the disclosure is not limited in its application to the details of construction and the arrangements of components set forth in the following description or illustrated in the drawings. The disclosure is capable of other example embodiments and of being practiced or being carried out in various ways. Also, it is to be understood that the phraseology and terminology used herein is for the purpose of description and should not be regarded as limiting.

Some of the techniques described herein may be implemented by one or more computer programs executed by one or more processors residing, for example on a power tool. The computer programs include processor-executable instructions that are stored on a non-transitory tangible computer readable medium. The computer programs may also include stored data. Non-limiting examples of the non-transitory tangible computer readable medium are nonvolatile memory, magnetic storage, and optical storage.

Some portions of the above description present the techniques described herein in terms of algorithms and symbolic representations of operations on information. These algorithmic descriptions and representations are the means used by those skilled in the data processing arts to most effectively convey the substance of their work to others skilled in the art. These operations, while described functionally or logically, are understood to be implemented by computer programs. Furthermore, it has also proven convenient at times to refer to these arrangements of operations as modules or by functional names, without loss of generality.

Unless specifically stated otherwise as apparent from the above discussion, it is appreciated that throughout the description, discussions utilizing terms such as “processing” or “computing” or “calculating” or “determining” or “displaying” or the like, refer to the action and processes of a computer system, or similar electronic computing device, that manipulates and transforms data represented as physical (electronic) quantities within the computer system memories or registers or other such information storage, transmission or display devices.

Certain aspects of the described techniques include process steps and instructions described herein in the form of an algorithm. It should be noted that the described process steps and instructions could be embodied in software, firmware or hardware, and when embodied in software, could be downloaded to reside on and be operated from different platforms used by real time network operating systems.

The foregoing description of the example embodiments has been provided for purposes of illustration and description. It is not intended to be exhaustive or to limit the disclosure. Individual elements or features of a particular example embodiment are generally not limited to that particular example embodiment, but, where applicable, are interchangeable and can be used in a selected example embodiment, even if not specifically shown or described. The same may also be varied in many ways. Such variations are not to be regarded as a departure from the disclosure, and all such modifications are intended to be included within the scope of the disclosure.

Example embodiments are provided so that this disclosure will be thorough, and will fully convey the scope to those who are skilled in the art. Numerous specific details are set forth such as examples of specific components, devices, and methods, to provide a thorough understanding of example embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

Numerous modifications may be made to the example implementations described above. These and other implementations are within the scope of this application.

1. A battery pack comprising:
a first printed circuit board;
a second printed circuit board; and
a PCB spacer, the PCB spacer including a housing and at least two board-to-board terminals, the PCB spacer housing injection molded around the board-to-board terminals;
the first printed circuit board coupled to a first side of the PCB spacer and the second printed circuit board coupled to a second side of the PCB spacer, the first side of the PCB spacer being opposed to the second side of the PCB spacer.

2. The battery pack, as recited in claim 1, wherein the board-to-board terminals electrically connect the first printed circuit board to the second printed circuit board.

3. The battery pack, as recited in claim 1, wherein the first printed circuit board includes terminal holes to receive the board-to-board terminals and the second PCB includes terminal holes to receive the board-to-board terminals.

4. The battery pack, as recited in claim 3, wherein the first printed circuit board terminal holes are electrically coupled to components mounted on the first printed circuit board and the second printed circuit board terminal holes are electrically coupled to components mounted on the second printed circuit board.

5. The battery pack, as recited in claim 1, wherein the board-to-board terminals comprise a conductive metal material.

6. The battery pack, as recited in claim 1, wherein the spacer housing has a generally planar, rectangular shape.

7. The battery pack, as recited in claim 1, wherein the PCB spacer comprises a plastic material.

8. The battery pack, as recited in claim 1, wherein the PCB spacer is formed by an injection molding process.

9. The battery pack, as recited in claim 1, wherein the spacer housing includes at least one clip extending from the first side of the spacer housing and the clip clips onto the first printed circuit board to couple and hold the spacer housing on the first printed circuit board.

10. The battery pack, as recited in claim 1, further comprising a first battery strap, the first battery strap electrically and mechanically coupled to the first PCB.

11. The battery pack, as recited in claim 10, wherein the first battery strap includes an end that is received in a first battery strap hole in the first PCB.

12. The battery pack, as recited in claim 11, wherein the first battery strap hole is electrically coupled to components mounted on the first printed circuit board.

13. The battery pack, as recited in claim 1, further comprising a battery pack housing, the battery pack housing forming an interior cavity; a set of battery cells; a battery cell holder housing the set of battery cells, the battery cell holder positioned within the interior cavity, the first printed circuit board being coupled to the battery cell holder.

14. The battery pack, as recited in claim 10, wherein the first battery strap is electrically coupled to a contact pad that is electrically connected to a most negative terminal of the set of battery cells.

15. The battery pack, as recited in claim 1, wherein the PCB spacer includes an interior opening defined by sides of the spacer housing, the interior opening receives one or more of a plurality of components mounted on a surface of the first printed circuit board facing the PCB spacer.

16. The battery pack, as recited in claim 15, wherein the interior opening is filled with a potting material to protect the mounted components from contaminants.

17. The battery pack, as recited in claim 1, further comprising a hold-down screw mechanically coupling the second printed circuit board and the PCB spacer to the first printed circuit board.

18. The battery pack, as recited in claim 17, wherein the first printed circuit board includes a threaded surface mounted nut and the hold-down screw is received by and screwed into the nut.
